(19) United States
(12) Patent Application Publication
(10) Pub. No.: US 2024/0405731 A1
(43) Pub. Date: Dec. 5, 2024

(54) SYSTEMS AND METHODS FOR PROVIDING AN ANALOG OUTPUT SIGNAL USING A CLASS-G AMPLIFIER

(71) Applicant: Maxim Integrated Products, Inc., San Jose, CA (US)

(72) Inventors: Arman Hematy, Camas, WA (US); Clemens Maria Hammerschmied, Sunnyvale, CA (US)

(21) Appl. No.: 18/674,206

(22) Filed: May 24, 2024

Related U.S. Application Data
(60) Provisional application No. 63/505,329, filed on May 31, 2023.

(51) Int. Cl. H03F 3/21; H03M 1/66

(52) U.S. Cl. CPC H03F 3/21; H03M 1/66

(57) ABSTRACT

A method for providing an analog output signal includes (a) amplifying an analog first internal signal using a first Class-G amplifier to generate an analog first output signal, (b) providing the analog first output signal to a first load, and (c) configuring the first Class-G amplifier for an impedance of the first load by selecting one of a plurality of power supply rails to power the first Class-G amplifier at least partially based on a voltage across the first load. In some embodiments, an impedance of the first load may range from zero to 1,000 ohms.

### RELATED APPLICATIONS

This application claims benefit of U.S. Provisional Patent Application No. 63/505,329, filed on May 31, 2023, which is incorporated herein by reference.

### BACKGROUND

Analog communication is widely used in factory automation applications and in process control applications. For example, programmable logic controllers, programmable automation controllers, and digital control systems, which are frequently used in factory automation applications and in process control applications, are commonly configured to generate analog output signals.

### BRIEF DESCRIPTION OF THE DRAWINGS

FIG. 1 is a block diagram of an electrical environment including a programmable controller and a load.

FIG. 2 is a block diagram of an electrical environment including a system for providing an analog output signal using a Class-G amplifier, according to an embodiment.

FIG. 3 is a block diagram of an electrical environment including an output module configured to provide an analog output signal using a Class-G amplifier, according to an embodiment.

FIG. 4 is a block diagram of an electrical environment including a programmable controller including an instance of the FIG. 3 output module, according to an embodiment.

FIG. 5 is a block diagram of an electrical environment including an alternate embodiment of the FIG. 4 programmable controller that is configured to support a plurality of output channels, according to an embodiment.

FIG. 6 is a block diagram of one possible embodiment of the FIG. 2 Class-G amplifier.

FIG. 7 is a block diagram of an alternate embodiment of the FIG. 6 Class-G amplifier.

FIG. 8 is a block diagram of an embodiment of the FIG. 3 output module including a Class-G amplifier similar to the FIG. 7 Class-G amplifier.

FIG. 9 is a schematic diagram of another possible embodiment of the FIG. 2 Class-G amplifier.

FIG. 10 is a schematic diagram of another possible embodiment of the FIG. 2 Class-G amplifier.

FIG. 11 is a schematic diagram of another possible embodiment of the FIG. 2 Class-G amplifier.

FIG. 12 is a block diagram of an alternate embodiment of the FIG. 6 Class-G amplifier configured to select one of three different power supply rails for powering the Class-G amplifier.

### DETAILED DESCRIPTION OF THE EMBODIMENTS

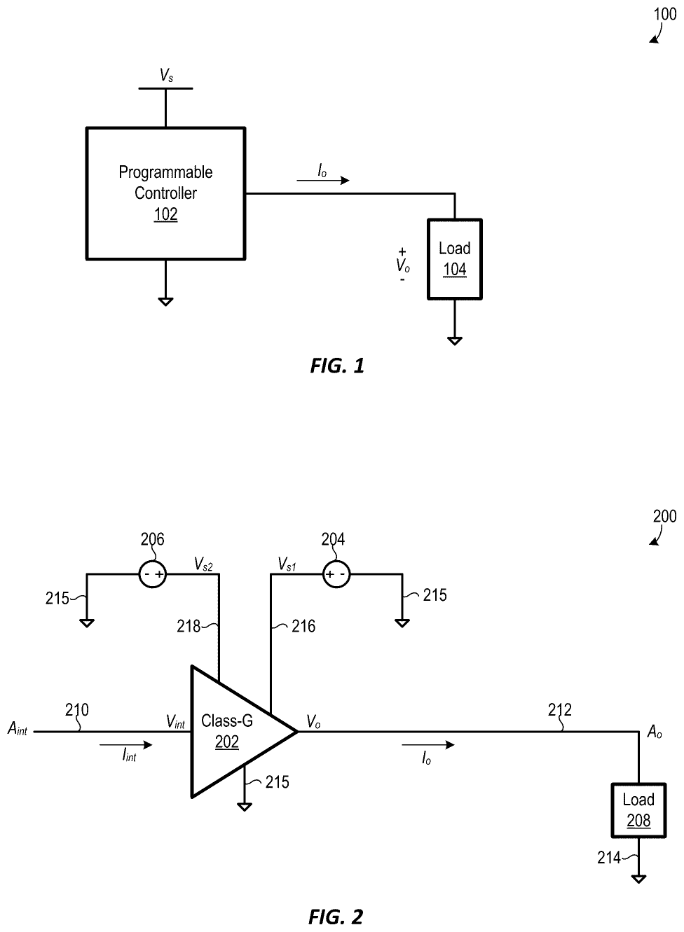

An analog signal generated by a programmable controller, such as a programmable logic controller (PLC), a programmable automation controller (PAC), or a programmable controller of a digital control system (DCS), may need to drive a load having a wide range of possible impedance values. For example, FIG. 1 is a block diagram of an electrical environment 100 including a programmable controller 102 and a load 104. Programmable controller 102 is powered from a power supply having a fixed voltage Vₛ, and programmable controller 102 is configured to generate an analog output current signal Iₒ having a magnitude of up to 20 milliamperes (mA). In this example, load 104 has an impedance that may range between zero and 1,000 ohms. Consequently, a voltage Vₒ across load 104 may significantly vary accordingly to impedance of load 104. For example, if analog output current signal Iₒ has a magnitude of 20 mA and load 104 has an impedance of 1,000 ohms, magnitude of voltage Vₒ is 20 volts. On the other extreme, if analog output current signal Iₒ has a magnitude of 20 mA and load 104 has an impedance of zero, magnitude of voltage Vₒ is zero.

Low values of voltage Vₒ may result in significant power dissipation in programmable controller 102. For example, assume that analog output current signal Iₒ has a magnitude of 20 mA, magnitude of voltage Vₛ is 20 volts, and load 104 has an impedance of zero, such that magnitude of voltage Vₒ is zero. Power dissipation (P) in programmable controller 102 under this scenario is equal to P=(Iₒ)(Vₛ), and power dissipation in programmable controller 102 is therefore P=(20 mA)(20 volts)=0.400 watts (W)=400 milliwatts (mW). While 400 mW power dissipation in programmable controller 102 may be acceptable in some applications, such relatively large power dissipation may limit the quantity of output channels that can be supported by a single programmable controller due to inability to adequately cool the programmable controller if multiple channels are driving low-impedance loads. For example, assume that programmable controller 102 is modified to support 8 output channels, i.e., programmable controller 102 is configured to generate 8 different analog output current signals for powering 8 different loads. Power dissipation in programmable controller 102 could be as high as 3.2 watts under this scenario, and it may therefore be challenging to adequately cool programmable controller 102, especially in applications where programmable controller 102 is within a cabinet that restricts transfer of heat away from programmable controller 102. Cooling challenges may be particularly acute in applications of programmable controller 102 where forced air cooling is undesirable, such as in dusty applications or in noise-sensitive applications.

Disclosed herein are systems and methods for providing an analog output signal using a Class-G amplifier which may help mitigate the problems discussed above. Particular embodiments of the new systems and methods configure a Class-G amplifier for an impedance of a load by selecting one of a plurality of power supply rails to power the Class-G amplifier at least partially based on a voltage across the load, thereby helping minimize power dissipation when the load has a low impedance. Additionally, some embodiments use power supplies having constant voltage magnitudes, which promotes power supply simplicity. Furthermore, certain embodiments share one or more power supplies among multiple output channels, thereby promoting low system cost, small system size, and system simplicity. Accordingly, the new systems and methods may enable a programmable controller to support a greater quantity of output channels than would be feasible using conventional technology.

FIG. 2 is a block diagram of an electrical environment 200, which includes one embodiment of the new systems for providing an analog output signal using a Class-G amplifier. Electrical environment 200 includes a Class-G amplifier 202, a first power supply 204, a second power supply 206, and a load 208. Class-G amplifier 202 is electrically coupled between an internal node 210 and an output node 212, and load 208 is electrically coupled between output node 212 and a reference node 214. Reference node 214 is depicted as being a ground node, such as an earth ground node or a chassis ground node. It is understood, though, that reference node 214 need not be a ground node, and reference node 214 accordingly could be at a different electrical potential than an earth ground or a chassis ground. Each of first power supply 204 and second power supply 206 is electrically coupled between Class-G amplifier and a reference node 215. First power supply 204 is configured to power a first power supply rail 216 having a voltage Vₛ₁, and second power supply 206 is configured to power a second power supply rail 218 having a voltage Vₛ₂. Voltage Vₛ₂ has a larger magnitude than voltage Vₛ₁. For example, in certain embodiments Vₛ₁ is equal to 10 volts, and Vₛ₂ is equal to 20 volts. Class-G amplifier 202 is electrically referenced to reference node 215. Reference node 215 is depicted as being a ground node, such as an earth ground node or a chassis ground node. It is understood, though, that reference node 215 need not be a ground node, and reference node 215 accordingly could be at a different electrical potential than an earth ground or a chassis ground. Additionally, reference node 215 could be at a different electrical potential than reference node 214.

While first power supply 204 and second power supply 206 are depicted as being external to Class-G amplifier 202, in some alternate embodiments, one or both of first power supply 204 and second power supply 206 are at least partially integrated with Class-G amplifier 202. Additionally, in some alternate embodiments, power supplies 204 and 206 are configured such that a voltage of first power supply rail 216 is equal to voltage Vₛ₁ of first power supply 204 and voltage of second power supply rail 218 is equal to the sum of voltage Vₛ₁ of first power supply 204 and voltage Vₛ₂ of second power supply 206. Furthermore, certain alternate embodiments of electrical environment 200 include two instances of each of first power supply 204 and second power supply 206, such as to provide split power supply rails, e.g., two power supply rails having respective voltages Vₛ₁ and −Vₛ₁, and two power supply rails having respective voltages Vₛ₂ and −Vₛ₂ (or two power supply rails having respective voltages [Vₛ₁+Vₛ₂] and −[Vₛ₁+Vₛ₂]. Moreover, in some other alternate embodiments of electrical environment 200, first power supply 204 and second power supply 206 are replaced with a single power supply having a selectable output voltage magnitude.

Class-G amplifier 202 is configured to amplify an analog internal signal Aᵢₙₜ on internal node 210 to generate an analog output signal Aₒ on output node 212. Analog internal signal Aᵢₙₜ is represented by one or more of (a) a current Iᵢₙₜ flowing into Class-G amplifier 202 via internal node 210 and (b) a voltage Vᵢₙₜ on internal node 210 with respect to reference node 215. Analog output signal Aₒ is represented by one or more of (a) a current Iₒ flowing out of Class-G amplifier 202 to output node 212 and (b) a voltage Vₒ on output node 212 with respect to reference node 215. Class-G amplifier 202 provides analog output signal Aₒ to load 208 via output node 212, and a voltage across load 208 is therefore the same as voltage Vₒ on output node 212.

In certain embodiments, impedance of load 208 may vary within a wide range of values independently of state of analog output signal Aₒ, e.g., impedance of load 208 may vary independently of magnitude and/or phase of analog output signal Aₒ. For example, in some embodiments, impedance of load 208 may range from zero and 750 ohms. As another example, in some other embodiments, impedance of load 208 may range from zero and 1,000 ohms. It is understood, though, that load 208 is not limited to any particular impedance range. For example, in some embodiments, impedance of load 208 may be greater than 1,000 ohms. As another example, in certain embodiments, a minimum impedance of load 208 is greater than zero. Additionally, in some embodiments, impedance of load 208 may not be known before Class-G amplifier 202 is deployed in electrical environment 200. In certain embodiments, load 208 includes an industrial device, such as an actuator, a valve, a motor, a motor starter, a solenoid, an alarm, a light, a relay, a counter, a pump, a fan, a printer, a heater, a compressor, a sequencer, etc.

Class-G amplifier 202 automatically configures itself for an impedance of load 208 by selecting one of first power supply rail 216 and second power supply rail 218 for its power source at least partially based on a magnitude of voltage (Vₒ) across load 208. For example, in certain embodiments, Class-G amplifier 202 is configured to select one of first power supply rail 216 and second power supply rail 218 for its power source directly based on magnitude of voltage across load 208, such as based on a relationship between the voltage across load 208 and a predetermined voltage threshold value. For instance, in certain embodiments, Class-G amplifier 202 (a) switches from being powered from first power supply rail 216 to second power supply rail 218 in response to magnitude of voltage across load 208 rising above a voltage threshold value and (b) switches from being powered from second power supply rail 218 to first power supply rail 216 in response to magnitude of voltage across load 208 falling below the voltage threshold value. In some other embodiments, Class-G amplifier 202 is configured to select one of first power supply rail 216 and second power supply rail 218 for its power source indirectly based on magnitude of voltage across load 208, such as by (a) determining impedance of load 208 based on voltage across load 208 and current flowing through load 208 and (b) selecting one of first power supply rail 216 and second power supply rail 218 for its power source based on determined impedance of load 208. For example, in some embodiments, Class-G amplifier 202 (a) switches from being powered from first power supply rail 216 to second power supply rail 218 in response to impedance of load 208 rising above an impedance threshold value and (b) switches from being powered from second power supply rail 218 to first power supply rail 216 in response to impedance of load 208 falling below the impedance threshold value. In some embodiments, Class-G amplifier 202 includes circuitry configured to determine voltage across load 208 and select one of first power supply rail 216 and second power supply rail 218 at least partially based on the determined voltage across load 208, while in some other embodiments, Class-G amplifier 202 is configured to automatically switch between first power supply rail 216 and second power supply rail 218 without use of voltage determination circuitry.

Accordingly, in particular embodiments, Class-G amplifier 202 has a relatively small power supply voltage (Vₛ₁) when voltage across load 208 is below a voltage threshold value (or when impedance of load 208 is below an impedance threshold value), and Class-G amplifier 202 has a relatively large power supply voltage (Vₛ₂) when voltage across load 208 is above the voltage threshold value (or when impedance of load 208 is above the impedance threshold value). Such feature helps minimize power dissipation in Class-G amplifier 202 when load 208 has a low impedance, while promoting ability of Class-G amplifier 202 to drive load 208 when load 208 has a high impedance.

For example, assume that (a) Vₛ₁ is 10 volts, (b) Vₛ₂ is 20 volts, and (c) Iₒ is 20 mA, and (d) Class-G amplifier 202 is configured to switch between first power supply rail 216 and second power supply rail 218 based on a voltage threshold value of 8 volts. Additionally, assume that load 208 has an impedance of 750 ohms. Under this scenario, voltage across load 208 would be 15 volts because Iₒ is 20 mA and impedance of load is 750 ohms, and Class-G amplifier 202 would therefore select second power supply rail 218 as its power source because the voltage across load 208 is greater than the voltage threshold value of 8 volts. The relatively high voltage (20 volts) of second power supply rail 218 enables Class-G amplifier 202 to adequately drive the high impedance value (750 ohm) of load 208. Now assume that load 208 has an impedance of zero. In this scenario, voltage across load 208 would be zero because the impedance of load 208 is zero, and Class-G amplifier 202 would therefore select first power supply rail 216 as its power source because the voltage across load 208 is less than the voltage threshold value of 8 volts. Consequently, power dissipation (P) in Class-G amplifier would be given by P=(Iₒ)(Vₛ₁)=(20 mA)(10 volts)=0.200 W=200 mW. It should be noted that the 200 mW power dissipation is only half of the 400 mW power dissipation of programmable controller 102 of FIG. 1 when providing a 20 mA output current to load a having an impedance of zero. Accordingly, use of Class-G amplifier 202 to power load 208 promotes low power dissipation when load 208 has a low impedance, without impairing ability to drive load 208 when the load has a high impedance. Such ability of Class-G amplifier 202 to drive a load having a wide possible impedance range may be particularly advantageous in embodiments where impedance of load 208 is not known before deployment of Class-G amplifier 202 in electrical environment 200.

Electrical environment 200 could be modified to include one or more additional power supplies, such that Class-G amplifier 202 automatically configures itself for impedance of load 208 by selecting one or more of three power supply rails for its power source, at least partially based on a magnitude of voltage across load 208. Additionally, certain embodiments of Class-G amplifier 202 are configured to present analog output signal Aₒ as either current Iₒ or voltage Vₒ, depending on the impedance of load 208. For example, in particular embodiments, (a) Class-G amplifier 202 switches from representing analog output signal Aₒ by current Iₒ to representing analog output signal Aₒ by voltage Vₒ in response to impedance of load 208 rising above an impedance threshold value, and (b) Class-G amplifier 202 switches from representing analog output signal Aₒ by voltage Vₒ to representing analog output signal Aₒ by current Iₒ in response to impedance of load 208 falling below the impedance threshold value.

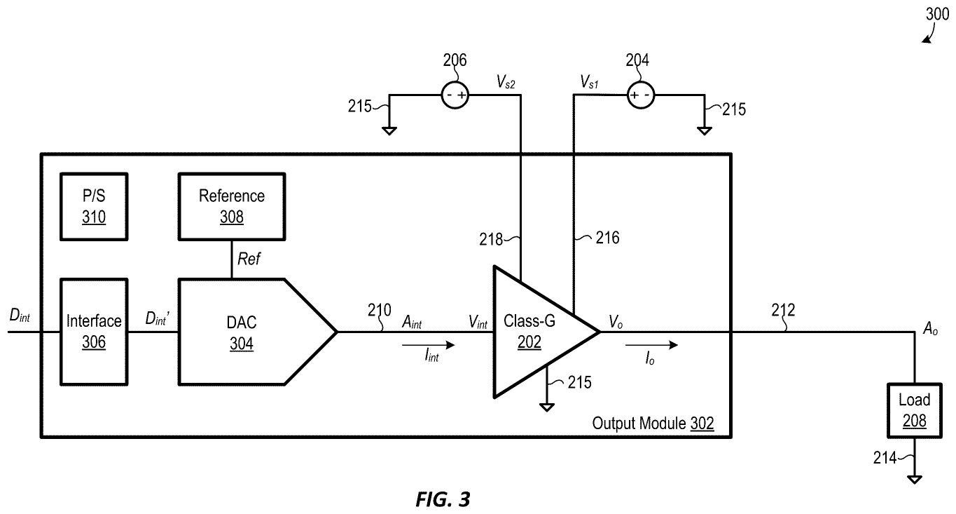

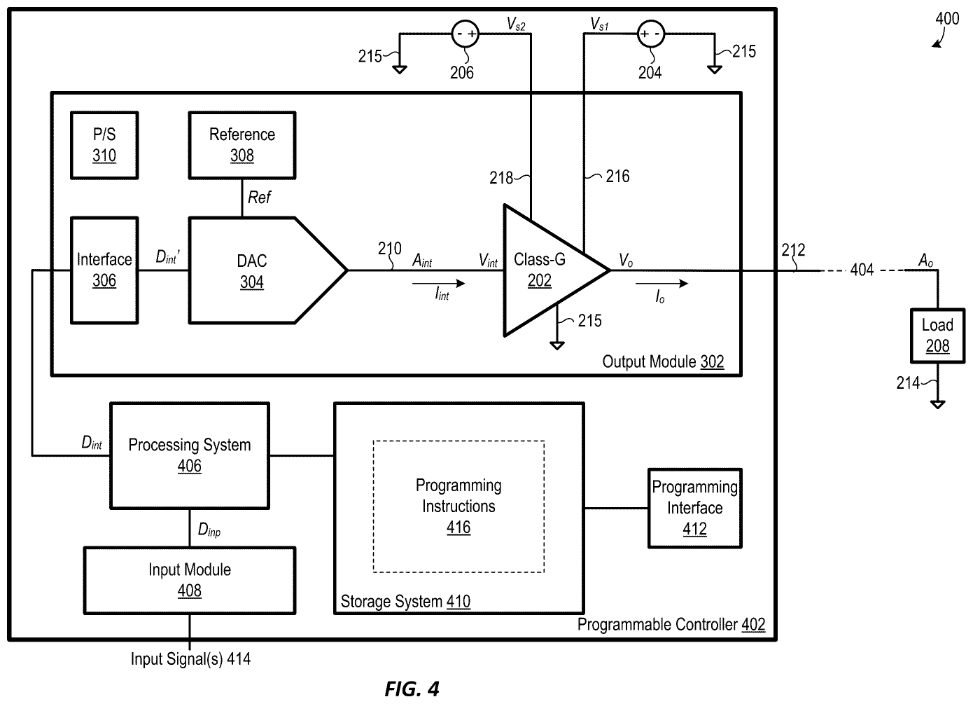

One application of the new systems and methods is in an output module, such as an output module used in an industrial application. For example, FIG. 3 is a block diagram of an electrical environment 300 including the elements of electrical environment 200 (FIG. 2) in an output module 302 application. Class-G amplifier 202 is part of output module 302, while load 208, first power supply 204, and second power supply 206 are external to output module 302. However, in some alternate embodiments, one or more of first power supply 204 and second power supply 206 are internal to output module 302. Output module 302 further includes a digital-to-analog (DAC) converter 304, an interface 306, a reference 308, and power supply circuitry 310. In certain embodiments, DAC 304 is a 16 bit DAC, and in particular embodiments, reference 308 has a tolerance of 10 part per million (ppm). Power supply circuitry 310 provides one or more power supply rails (not shown) for powering DAC 304, interface 306, and reference 308. Interface 306 is configured to receive a digital internal signal Dᵢₙₜ from outside of output module 302, and interface 306 is configured to provide the received digital internal signal to DAC 304 as a digital internal signal Dᵢₙₜ′. In some embodiments, digital internal signal Dᵢₙₜ′ is identical to digital internal signal Dᵢₙₜ, while in other embodiments, digital internal signal Dᵢₙₜ′ is derived from, but is not identical to, digital internal signal Dᵢₙₜ. In particular embodiments, Dᵢₙₜ is a serial communication signal. DAC 304 is configured to convert digital internal signal Dᵢₙₜ′ to analog input signal Aᵢₙₜ using a reference signal Ref generated by reference 308. Reference signal Ref is either a voltage signal or a current signal. Class-G amplifier 202 is configured to generate analog output signal Aₒ and provide analog output signal Aₒ to load 208 in the same manner as discussed above with respect to FIG. 2.

Some embodiments of interface 306 are additionally configured to control one or more aspects of output module 302. For example, in certain embodiments, interface 306 controls whether Class-G amplifier 202 is powered from first power supply rail 216 or second power supply rail 218, at least partially based on voltage across load 208 as measured by Class-G amplifier 202 and provided to interface 306.

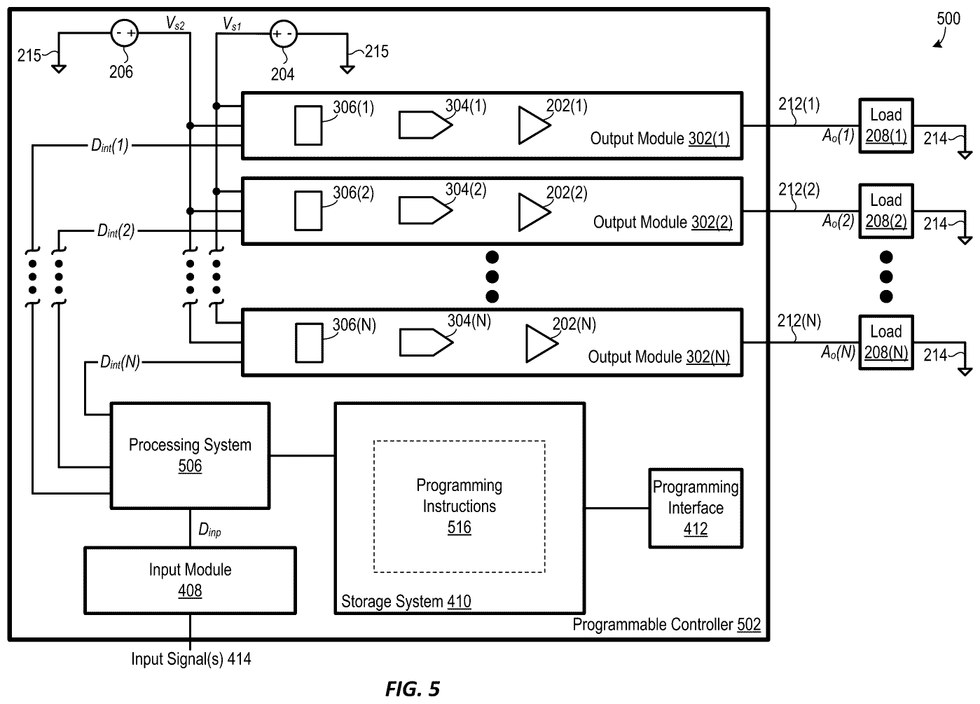

Possible applications of output module 302 include, but are not limited to, a programmable controller application, such as a PLC application, a PAC application, or a DCS application. For example, FIG. 4 is a block diagram of an electrical environment 400 including a programmable controller 402, an electrical cable 404, and an instance of load 208. Electrical cable 404 electrically couples an output of Class-G amplifier 202 to load 208, and electrical cable 404 is therefore part of output node 212. In certain embodiments, electrical cable 404 is relatively long, e.g., tens of meters in length, hundreds of meters in length, or even longer.

Programmable controller 402 includes an instance of output module 302 (FIG. 3), a processing system 406, an input module 408, a storage system 410, and an optional programming interface 412. Two or more of the aforesaid elements of programmable controller 402 could be partially or fully combined without departing from scope hereof. Input module 408 is configured to receive one or more input signals 414 from outside of programmable controller 402 and provide the one or more input signals to processing system 406 as digital input signals Dᵢₙₚ. Input signals 414 may be analog input signals, digital signals, or a combination of analog and digital input signals. In embodiments where input signals 414 include analog input signals, input module 408 includes at least one ADC (not shown). In some embodiments, input signals 414 are generated by one or more of switch, a sensor, and an encoder.

Storage system 410 stores programming instructions 416, such as in the form of software and/or firmware, for execution by processing system 406. Storage system 410 is optionally configured to store additional information, such as input signals 414 and/or working information for use by processing system 406. Processing system 406 is configured to generate digital internal signal Dᵢₙₜ at least partially according to programming instructions 416 and optionally further according to one or more of input signals 414. Output module 302 is configured to generate analog output signal Aₒ in response to digital internal signal Dᵢₙₜ as discussed above with respect to FIGS. 2 and 3. In certain embodiments where Dᵢₙₜ is a serial communication signal, each of processing system 406 and interface 306 are controlled by a common clock (not shown), or each of processing system 406 and interface 306 include respective clocks (not shown) that are synchronized. Programmable controller 402 may be, for example, a programmable logic controller, a programmable automation controller, or a programmable controller of a digital control system, such as based on the configuration of programming instructions 416. For example, programming instructions 416 may include (a) instructions that cause programmable controller 402 to operate as a programmable logic controller, (b) instructions that cause programmable controller 402 to operate as a programmable automation controller, or (c) instructions that cause programmable controller 402 to operate as a programmable controller of a digital control system.

Optional programming interface 412 enables creation and/or modification of programming instructions 416. Certain embodiments of programming interface 412 include one or more user input devices and/or user output devices, such as a keyboard, a switch, a mouse, a touch pad, a screen, a monitor, a printer, etc. Additionally, some embodiments of programming interface 412 include one or more interfaces to an external system, such as an electrical interface (e.g., a Universal Serial Bus (USB) electrical interface and/or or an Ethernet electrical interface), a wireless interface (e.g., a Bluetooth wireless interface, a Wi-Fi wireless interface, a cellular wireless interface, and/or a satellite wireless interface), an optical interface (e.g., an optical cable interface and/or a free space optical interface), and/or a logical interface (e.g., an application programming interface (API)).

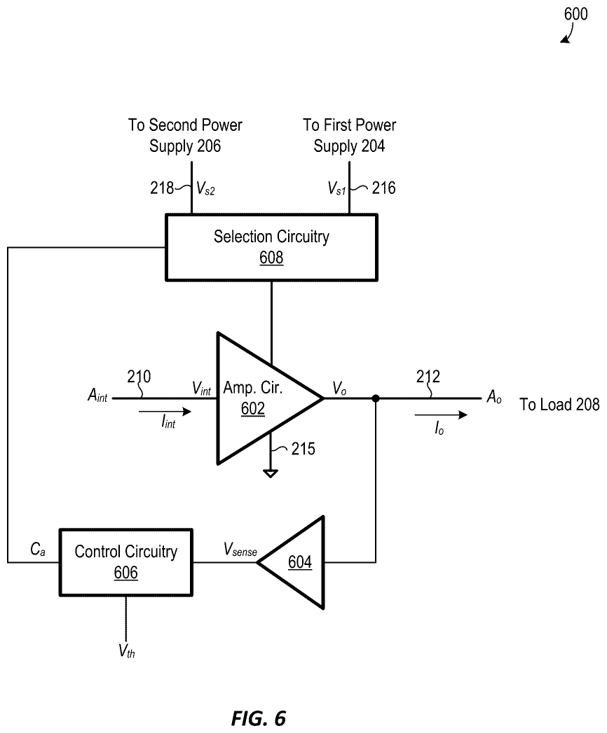

Programmable controller 402 could be modified to support additional channels, i.e., to be capable of generating multiple instances of analog output signal Aₒ for driving a plurality of different respective loads. For example, FIG. 5 is a block diagram of an electrical environment 500 including a programmable controller 502 and N loads 208, where N is an integer greater than one. In this document, specific instances of an item may be referred to by use of a numeral in parentheses (e.g. load 208(1)) while numerals without parentheses refer to any such item (e.g. loads 208). Programmable controller 502 is an alternate embodiment of programmable controller 402 (FIG. 4) include N output modules 302. FIG. 5 symbolically shows interface 306, DAC 304, and Class-G amplifier 202 of each output module 302, but other elements of output modules 302, as well as connections between elements within output modules 302, are not shown in FIG. 5 for illustrative clarity. It is understood, though, that each output module 302 of FIG. 5 is configured as discussed above with respect to FIG. 3. Programmable controller 502 additionally includes a processing system 506 and programming instructions 516 in place of processing system 406 and programming instructions 416, respectively. Processing system 506 in similar to processing system 406 of FIG. 4 except that processing system 506 is configured to generate N digital internal signals Dᵢₙₜ, i.e., a respective digital internal signal Dᵢₙₜ for each output module 302, instead of a single digital internal signal Dᵢₙₜ. For example, in certain embodiments, processing system 506 is configured to generate each digital internal signal Dᵢₙₜ at least partially according to programming instructions 516 and optionally further according to one or more of input signals 414. In certain embodiments, each digital internal signal Dᵢₙₜ may have a different respective value at any given time, while in certain other embodiments, two or more digital internal signal Dᵢₙₜ have a common value at any given time. Programming instructions 516 are similar to programming instructions 416 except that programming instructions 516 are capable of supporting generation of N digital internal signals Dᵢₙₜ, instead of solely a single digital internal signal Dᵢₙₜ.

Each output module 302 is electrically coupled to a respective load 208 via a respective output node 212. Each output node 212 may be considered a respective output channel of programmable controller 502, and programmable controller 502 is accordingly an N output channel programmable controller. Each output module 302 is configured to generate an analog output signal Aₒ in response to a respective digital internal signal Dᵢₙₜ, in the manner discussed above with respect to FIGS. 2 and 3.

It should be noted that all N output modules 302 share each of first power supply 204 and second power supply 206, which promotes small size, low cost, and low complexity of programmable controller 502. In certain alternate embodiments, though, programmable controller 502 includes a respective first power supply 204 and/or a respective second power supply 206 for each output module 302. Additionally, some other alternate embodiments of programmable controller 502 include (a) more than one, but fewer than N, first power supplies 204 and (b) more than one, but fewer than N, second power supplies 206.

Programmable controller 502 could include additional elements without departing from the scope hereof. For example, some alternate embodiments of programmable controller 502 further include one or more output modules (not shown) configured to generate digital output signals (not shown) in response to additional digital internal signals (not shown) generated by processing system 506, such that the programable controller 502 is capable of providing digital output signals as well as analog output signals Aₒ. As another example, programmable controller 502 could be modified to include one or more additional input modules, one or more additional processing systems, and/or one or more additional storage systems.

Discussed below with respect to FIGS. 6-12 are several examples of how Class-G amplifier 202 could be embodied. It is understood, though, that Class-G amplifier 202 is not limited to the example embodiments of FIGS. 6-12.

FIG. 6 is a block diagram of a Class-G amplifier 600, which is one possible embodiment of Class-G amplifier 202. Class-G amplifier 600 includes amplification circuitry 602, voltage sensing circuitry 604, control circuitry 606, and selection circuitry 608. Two or more of the elements of Class-G amplifier 600 may be partially or fully combined. Additionally, one or more elements of Class-G amplifier 600 may be partially or fully combined with one or more elements external to Class-G amplifier 600, such as with one or more elements of an output module including Class-G amplifier 600. Additionally, Class-G amplifier 600 may include additional elements (not shown), such as compensation elements.

Amplification circuitry 602 is electrically coupled between internal node 210 and output node 212, and amplification circuitry 602 is configured to amplify analog internal signal Aᵢₙₜ to generate analog output signal Aₒ. Voltage sensing circuitry 604 is configured to determine voltage across load 208 by sensing voltage Vₒ and by generating a signal Vₛₑₙₛₑ representing voltage across load 208. Selection circuitry 608 is configured to select one of first power supply rail 216 and second power supply rail 218 for powering amplification circuitry 602 based on a control signal Cₐ. Control circuitry 606 is configured to generate control signal Cₐ at least partially based on signal Vₛₑₙₛₑ. For example, in certain embodiments, control circuitry 606 is configured to (a) generate control signal Cₐ to cause selection circuitry 608 to select first power supply rail 216 for powering amplification circuitry 602 in response to signal Vₛₑₙₛₑ indicating that voltage across load 208 is less than a voltage threshold Vₜₕ and (b) generate control signal Cₐ to cause selection circuitry 608 to select second power supply rail 218 for powering amplification circuitry 602 in response to signal Vₛₑₙₛₑ indicating that voltage across load 208 is at least voltage threshold Vₜₕ. In some embodiments, voltage threshold Vₜₕ is provided to control circuitry 606 by an external source (not shown), as illustrated in FIG. 6. In some other embodiments, voltage threshold Vₜₕ is generated within control circuitry 606, and in these embodiments, voltage threshold Vₜₕ may be either fixed or programmable.

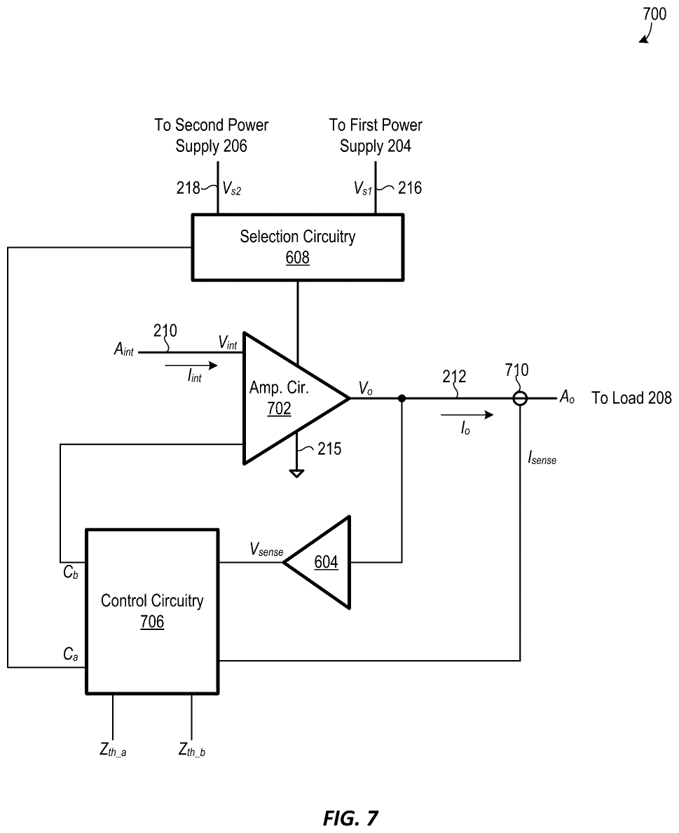

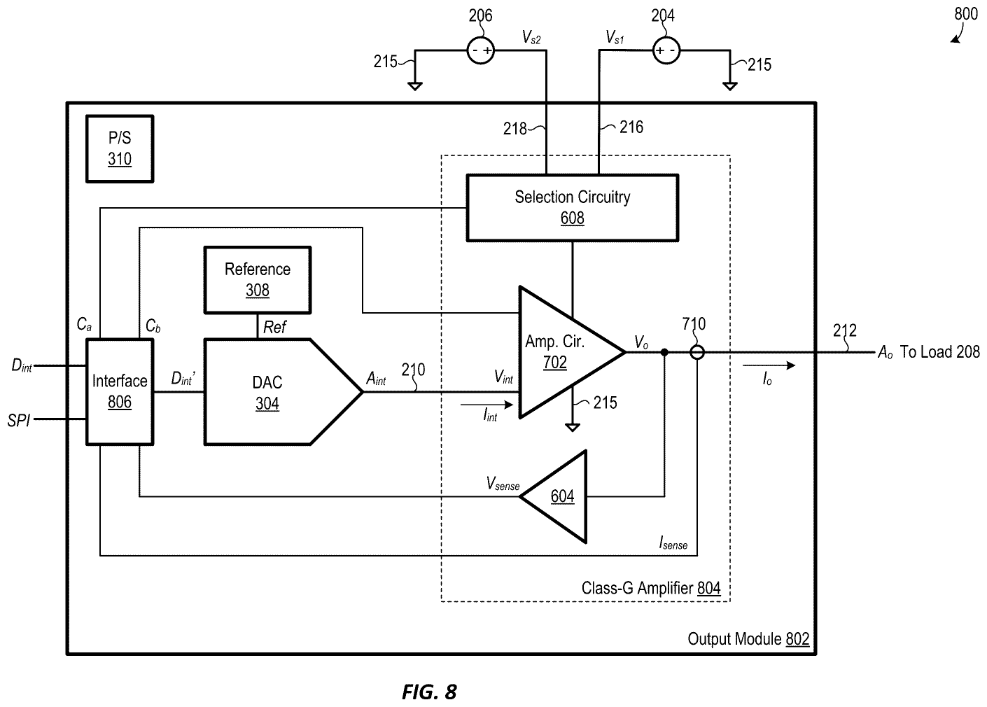

FIG. 7 is a block diagram of a Class-G amplifier 700, which is an alternate embodiment of Class-G amplifier 600 (FIG. 6). Class-G amplifier 700 differs from Class-G amplifier 600 in that (a) amplification circuitry 602 is replaced by amplification circuitry 702, (b) control circuitry 606 is replaced by control circuitry 706, and (c) Class-G amplifier 700 further includes current sensing circuitry 710. Two or more of the elements of Class-G amplifier 700 may be partially or fully combined. Additionally, one or more elements of Class-G amplifier 700 may be partially or fully combined with one or more elements external to Class-G amplifier 700, such as with one or more elements of an output module including Class-G amplifier 700. Additionally, Class-G amplifier 700 may include additional elements (not shown), such as compensation elements.

Amplification circuitry 702 is electrically coupled between internal node 210 and output node 212, and amplification circuitry 702 is configured to amplify analog internal signal Aᵢₙₜ to generate analog output signal Aₒ. Additionally, amplification circuitry 702 is configured to generate analog output signal Aₒ as either current Iₒ or voltage Vₒ based on a control signal C_{b}. Current sensing circuitry 710 is configured to generate a signal Iₛₑₙₛₑ representing current flowing to load 208 via output node 212. Control circuitry 706 is configured to (a) determine impedance of load 208 from signals Vₛₑₙₛₑ and Iₛₑₙₛₑ, e.g., by dividing signal Vₛₑₙₛₑ by signal Iₛₑₙₛₑ, and (b) generate each of control signals Cₐ and C_{b} at least partially based on the determined impedance of load 208. Accordingly, Class-G amplifier 700 selects either first power supply rail 216 or second power supply rail 218 for powering amplification circuitry 702 indirectly based on voltage across load 208, i.e., control circuitry 706 uses voltage across load 208 to determine impedance of load 208, and control circuity 706 uses impedance of load 208 to select either first power supply rail 216 or second power supply rail 218 for powering amplification circuitry 702.

In certain embodiments, control circuitry 706 is configured to (a) generate control signal Cₐ to cause selection circuitry 608 to select first power supply rail 216 for powering amplification circuitry 602 in response to impedance of load 208 being less than an impedance threshold Z_{th_a} and (b) generate control signal Cₐ to cause selection circuitry 608 to select second power supply rail 218 for powering amplification circuitry 602 in response to impedance of load 208 being at least impedance threshold Z_{th_a}. Additionally, in some embodiments, control circuitry 706 is configured to (a) generate control signal C_{b} to cause amplification circuitry 702 to generate analog output signal Aₒ as current Iₒ in response in response to impedance of load 208 being less than an impedance threshold Z_{th_b} and (b) generate control signal C_{b} to cause amplifier amplification circuitry 702 to generate analog output signal Aₒ as voltage Vₒ in response to impedance of load 208 being at least impedance threshold Z_{th_b}, where impedance threshold Z_{th_b} is different from impedance threshold Z_{th_a}. In certain alternate embodiments, impedance threshold Z_{th_b} is the same as impedance threshold Z_{th_a}. In some embodiments, impedance thresholds Z_{th_a} and Z_{th_b} are provided to control circuitry 706 by an external source (not shown), as illustrated in FIG. 7. In some other embodiments, one or more of impedance thresholds Z_{th_a} and Z_{th_b} are generated within control circuitry 706, and in these embodiments, the one or more impedance thresholds generated within control circuitry 706 may be either fixed or programmable.

Certain alternate embodiments of Class-G amplifier 700 are configured to determine impedance of load 208 by providing a test signal to load 208 and measuring a response of load 208 to the test signal. For example, in certain alternate embodiments of Class-G amplifier 700, amplification circuitry 702 is configured to drive load 208 with current Iₒ of a predetermined magnitude during a test mode, and voltage sensing circuitry 604 is configured to concurrently determine magnitude of voltage across load 208. Control circuitry 706 then determines impedance of load 208 by dividing the determined magnitude of the voltage across load 208 during the test mode by the predetermined magnitude of current Iₒ. Current sensing circuitry 710 is optionally omitted in these alternate embodiments. As another example, in some other alternate embodiments of Class-G amplifier 700, amplification circuitry 702 is configured to drive load 208 with voltage Vₒ of a predetermined magnitude during a test mode, and current sensing circuitry 710 is configured to concurrently determine magnitude of current Iₒ flowing to load 208. Control circuitry 706 then determines impedance of load 208 by dividing the predetermined magnitude of voltage Vₒ by the determined magnitude of the current Iₒ flowing to load 208 during the test mode. Voltage sensing circuitry 604 is optionally omitted in these alternate embodiments.

FIG. 8 is a block diagram of an output module 802, which is an embodiment of output module 302 (FIG. 3) where (a) Class-G amplifier 202 is implemented by a Class-G amplifier 804 and (b) interface 306 is embodied by an interface 806. Class-G amplifier 804 is like Class-G amplifier 700 of FIG. 7 except that control circuitry 706 is omitted, and functions of control circuitry 706 are instead performed by interface 806. Interface 806 is configured to receive a digital internal signal Dᵢₙₜ from outside of output module 802, and interface 806 is configured to provide the received digital internal signal to DAC 304 as a digital internal signal Dᵢₙₜ′, in a manner analogous to that discussed above with respect to interface 306.

Additionally, interface 806 is configured to generate control signals Cₐ and C_{b} at least partially based on signals Vₛₑₙₛₑ and Iₛₑₙₛₑ, as provided by Class-G amplifier 804. For example, in some embodiments, interface 806 is configured to (a) generate control signal Cₐ to cause selection circuitry 608 to select first power supply rail 216 for powering amplification circuitry 602 in response to impedance of load 208 being less than an impedance threshold Z_{th_a} and (b) generate control signal Cₐ to cause selection circuitry 608 to select second power supply rail 218 for powering amplification circuitry 602 in response to impedance of load 208 being at least impedance threshold Z_{th_a}. Additionally, in some embodiments, interface 806 is configured to (a) generate control signal C_{b} to cause amplification circuitry 702 to generate analog output signal Aₒ as current Iₒ in response in response to impedance of load 208 being less than an impedance threshold Z_{th_b} and (b) generate control signal C_{b} to cause amplification circuitry 702 to generate analog output signal Aₒ as voltage Vₒ in response to impedance of load 208 being at least impedance threshold Z_{th_b}. Certain embodiments of interface 806 enable each of Z_{th_a} and Z_{th_b} to be configured via an externally provided signal using a Serial Peripheral Interface (SPI).

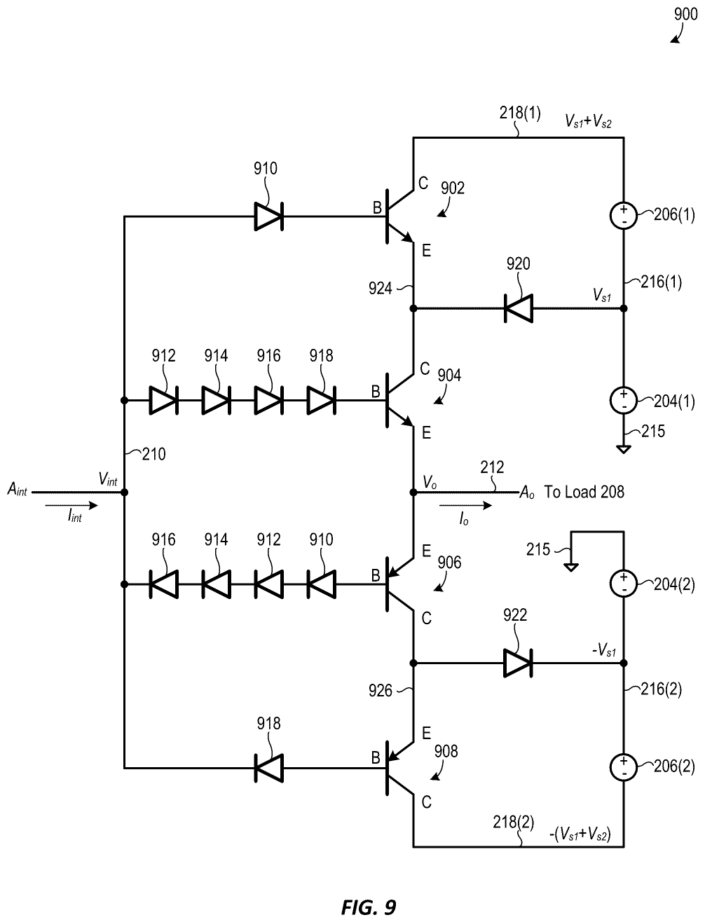

FIG. 9 is a schematic diagram of a Class-G amplifier 900, which is another possible embodiment of Class-G amplifier 202 (FIG. 2). Class-G amplifier 900 includes two instances of first power supply 204, two instances of second power supply 206, an NPN bipolar junction transistor (BJT) 902, an NPN BJT 904, a PNP BJT 906, a PNP BJT 908, and diodes 910-922. A base (B) of BJT 902 is electrically coupled to internal node 210 via diode 910, a collector (C) of BJT 902 is electrically coupled to second power supply rail 218 (1), and an emitter (E) of BJT 902 is electrically coupled to an amplifier node 924. Second power supply 206(1) is electrically coupled between second power supply rail 218(1) and first power supply rail 216(1), and diode 920 is electrically coupled between first power supply rail 216(1) and amplifier node 924. First power supply 204(1) is electrically coupled between first power supply rail 216(1) and reference node 215.

Diodes 912-918 are electrically coupled in series between internal node 210 and a base (B) of BJT 904, a collector (C) of BJT 904 is electrically coupled to amplifier node 924, and an emitter (E) of BJT 904 is electrically coupled to output node 212. Diodes 910-916 are electrically coupled in series between a base (B) of BJT 906 and internal node 210, an emitter (E) of BJT 906 is electrically coupled to output node 212, and a collector (C) of BJT 906 is electrically coupled to an amplifier node 926. A base (B) of BJT 908 is electrically coupled to internal node 210 via diode 918, an emitter (E) of BJT 908 is electrically coupled to amplifier node 926, and a collector (C) of BJT 908 is electrically coupled to second power supply rail 218(2). Second power supply 206(2) is electrically coupled between second power supply rail 218(2) and first power supply rail 216(2), and diode 922 is electrically coupled between amplifier node 926 and first power supply rail 216(2). First power supply 204(2) is electrically coupled between reference node 215 and first power supply rail 216(2).

Class-G amplifier 900 has split power supply rails. Specifically, first power supply rails 216(1) and 216(2) are at voltages Vₛ₁ and −Vₛ₁, respectively, and second power supply rails 218(1) and 218(2) are at voltages (Vₛ₁+Vₛ₂) and −(Vₛ₁+Vₛ₂), respectively. Class-G amplifier 900 automatically selects one of (a) first power supply rails 216(1) and 216(2) and (b) second power supply rails 218(1) and 218(2) based on voltage across load 208, without use of dedicated voltage sensing circuitry.

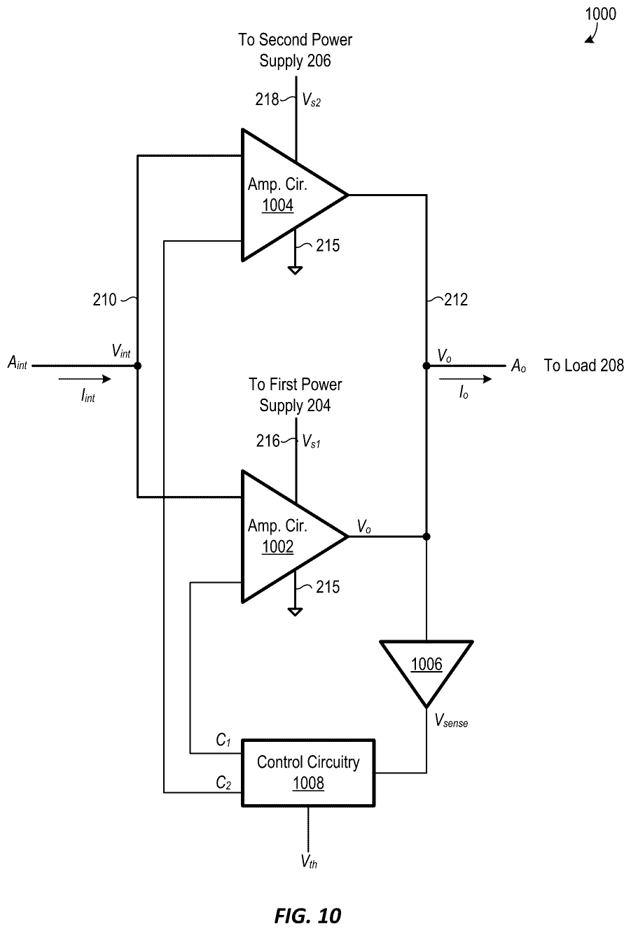

FIG. 10 is a schematic diagram of a Class-G amplifier 1000, which is another possible embodiment of Class-G amplifier 202 (FIG. 2). Class-G amplifier 1000 includes first amplification circuitry 1002, second amplification circuitry 1004, voltage sensing circuitry 1006, and control circuitry 1008. Two or more of the elements of Class-G amplifier 1000 may be partially or fully combined. Additionally, one or more elements of Class-G amplifier 1000 may be partially or fully combined with one or more elements external to Class-G amplifier 1000, such as with one or more elements of an output module including Class-G amplifier 1000. Furthermore, Class-G amplifier 1000 may include additional elements (not shown), such as compensation elements.

Voltage sensing circuitry 1006 is configured to determine voltage across load 208 by sensing voltage Vₒ and by generating a signal Vₛₑₙₛₑ representing voltage across load 208. Each of first amplification circuitry 1002 and second amplification circuitry 1004 is electrically coupled between internal node 210 and output node 212, and each of first amplification circuitry 1002 and second amplification circuitry 1004 is configured to amplify analog internal signal Aᵢₙₜ to generate analog output signal Aₒ. However, control circuitry 1008 controls first amplification circuitry 1002 and second amplification circuitry 1004 via respective control signals C₁ and C₂ such that only one of the two amplification circuitry operates at any given time, at least partially based on magnitude of voltage across load 208. For example, in certain embodiments, control circuitry 1008 is configured to (a) generate control signals C₁ and C₂ to cause first amplification circuitry 1002 to operate and second amplification circuitry 1004 to be inactive, in response to signal Vₛₑₙₛₑ indicating that voltage across load 208 is less than a voltage threshold Vₜₕ, and (b) generate control signals C₁ and C₂ to cause first amplification circuitry 1002 to be inactive and second amplification circuitry 1004 to operate, in response to signal Vₛₑₙₛₑ indicating that voltage across load 208 is at least voltage threshold Vₜₕ. As such, Class-G amplifier 1000 selects one of first power supply rail 216 and second power supply rail 218 for powering Class-G amplifier 1000 by determining which of first amplification circuitry 1002 and second amplification circuitry 1004 is active. In some embodiments, voltage threshold Vₜₕ is provided to control circuitry 1008 by an external source (not shown), as illustrated in FIG. 10. In some other embodiments, voltage threshold Vₜₕ is generated within control circuitry 1008, and in these embodiments, voltage threshold Vₜₕ may be either fixed or programmable.

Certain alternate embodiments of Class-G amplifier 1000 include current sense circuitry (not shown) in place of, or in addition to, voltage sensing circuitry 1006. Additionally, in some alternate embodiments of Class-G amplifier 1000, control circuitry 1008 uses impedance of load 208 to select either first amplification circuitry 1002 or second amplification circuitry 1004 to operate. For example, in certain alternate embodiments, control circuitry 1008 is configured to (a) generate control signals C₁ and C₂ to cause first amplification circuitry 1002 to operate and second amplification circuitry 1004 to be inactive, in response to impedance of load 208 being less than a threshold impedance threshold value and (b) generate control signals C₁ and C₂ to cause first amplification circuitry 1002 to be inactive and second amplification circuitry 1004 to operate, in response to impedance of load 208 being at least the impedance threshold value.

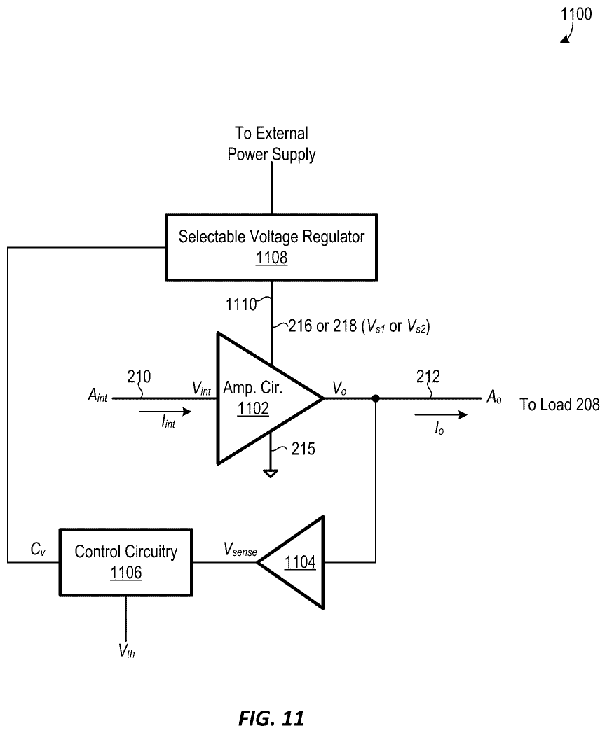

FIG. 11 is a block diagram of a Class-G amplifier 1100, which is another possible embodiment of Class-G amplifier 202 (FIG. 2). Class-G amplifier 1100 includes amplification circuitry 1102, voltage sensing circuitry 1104, control circuitry 1106, and a selectable voltage regulator 1108. Two or more of the elements of Class-G amplifier 1100 may be partially or fully combined. Additionally, one or more elements of Class-G amplifier 1100 may be partially or fully combined with one or more elements external to Class-G amplifier 1100, such as with one or more elements of an output module including Class-G amplifier 1100. Furthermore, Class-G amplifier 1100 may include additional elements (not shown), such as compensation elements.

Amplification circuitry 1102 is electrically coupled between internal node 210 and output node 212, and amplification circuitry 1102 is configured to amplify analog internal signal Aᵢₙₜ to generate analog output signal Aₒ. Voltage sensing circuitry 1104 is configured to determine voltage across load 208 by sensing voltage Vₒ and by generating a signal Vₛₑₙₛₑ representing voltage across load 208. Selectable voltage regulator 1108 is electrically coupled between an external power supply (not shown) and a power source node 1110 for amplification circuitry 1110. Selectable voltage regulator 1108 is configured to provide one of voltages Vₛ₁ and Vₛ₂ at power source node 1110 based on a control signal Cᵥ. Stated differently, power source node 1110 may be either (a) first power supply rail 216 at voltage Vₛ₁ or (b) second power supply rail 218 at voltage Vₛ₂, depending on the state of control signal Cᵥ. Selectable voltage regulator 1108 includes, for example, a selectable direct-current-to-direct-current (DC-to-DC) converter, a selectable charge pump, or even a selectable linear regulator in applications where significant power dissipation in the selectable voltage regulator is acceptable.

Control circuitry 1106 is configured to generate control signal Cᵥ at least partially based on signal Vₛₑₙₛₑ. For example, in certain embodiments, control circuitry 1106 is configured to (a) generate control signal Cᵥ to cause selectable voltage regulator 1108 to generate voltage Vₛ₁ at power source node 1110 in response to signal Vₛₑₙₛₑ indicating that voltage across load 208 is less than a voltage threshold Vₜₕ and (b) generate control signal Cᵥ to cause selectable voltage regulator 1108 to generate voltage Vₛ₂ and power source node 1110 in response to signal Vₛₑₙₛₑ indicating that voltage across load 208 is at least voltage threshold Vₜₕ. As such, Class-G amplifier 1100 selects one of first power supply rail 216 and second power supply rail 218 for powering Class-G amplifier 1100 by selecting an output voltage of selectable voltage regulator 1108. In some embodiments, voltage threshold Vₜₕ is provided to control circuitry 1106 by an external source (not shown), as illustrated in FIG. 11. In some other embodiments, voltage threshold Vₜₕ is generated within control circuitry 1106, and in these embodiments, voltage threshold Vₜₕ may be either fixed or programmable.

Certain alternate embodiments of Class-G amplifier 1100 include current sense circuitry (not shown) in place of, or in addition to, voltage sensing circuitry 1104. Additionally, in some alternate embodiments of Class-G amplifier 1100, control circuitry 1106 uses impedance of load 208 to select an output voltage of selectable voltage regulator 1108. For example, in certain alternate embodiments, control circuitry 1108 is configured to (a) generate control signal Cᵥ to cause voltage at power source node 1110 to be Vₛ₁, in response to impedance of load 208 being less than an impedance threshold value and (b) generate control signal Cᵥ to cause voltage at power source node 1110 to be Vₛ₂, in response to impedance of load 208 being at least the impedance threshold value.

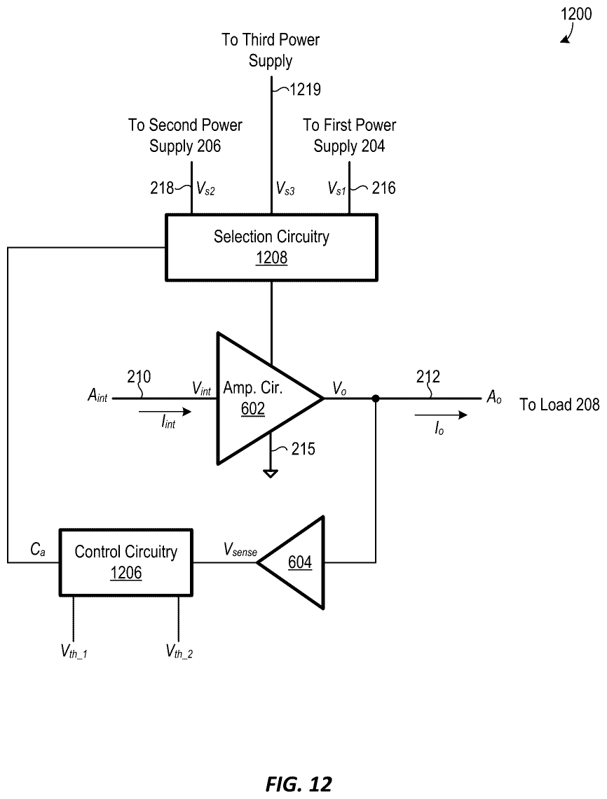

Referring again to FIG. 2, as discussed above, electrical environment 200 could be modified to include one or more additional power supplies, such that Class-G amplifier 202 automatically configures itself for impedance of load 208 by selecting one of three or more power supply rails for its power source, at least partially based on a magnitude of voltage across load 208. Accordingly, any of the example Class-G amplifiers of FIGS. 6-11 could be modified to select one of three or more different power supply rails for powering the Class-G amplifier at least partially based on a magnitude of voltage across load 208. For example, FIG. 12 is a block diagram of a Class-G amplifier 1200, which is an alternate embodiment of Class-G amplifier 600 (FIG. 6) configured to select one of three different power supply rails for powering the Class-G amplifier, at least partially based on magnitude of voltage across load 208. Class-G amplifier 1200 differs from Class-G amplifier 600 in that (a) control circuitry 606 is replaced with control circuitry 1206 and (b) selection circuitry 608 is replaced with selection circuitry 1208. Selection circuitry 1208 is configured to select one of first power supply rail 216, second power supply rail 218, and a third power supply rail 1219 for powering amplification circuitry 602 based on a control signal Cₐ. Third power supply rail 1219 is powered by a third power supply (not shown), and third power supply rail 1219 has a voltage Vₛ₃, where magnitude of voltage Vₛ₃ is different from each of magnitude of voltage Vₛ₂ and magnitude of voltage Vₛ₁. In certain embodiments, magnitude of voltage Vₛ₃ is larger than magnitude of voltage Vₛ₂, and magnitude of voltage Vₛ₂ is larger than magnitude of voltage Vₛ₁.

Control circuitry 1206 is configured to generate control signal Cₐ at least partially based on signal Vₛₑₙₛₑ. For example, in certain embodiments, control circuitry 1206 is configured to (a) generate control signal Cₐ to cause selection circuitry 1208 to select first power supply rail 216 for powering amplification circuitry 602 in response to signal Vₛₑₙₛₑ indicating that voltage across load 208 is less than a voltage threshold V_{th_1}, (b) generate control signal Cₐ to cause selection circuitry 1208 to select second power supply rail 218 for powering amplification circuitry 602 in response to signal Vₛₑₙₛₑ indicating that voltage across load 208 is at least voltage threshold V_{th_1} but less than a voltage threshold V_{th_2}, and (c) generate control signal Cₐ to cause selection circuitry 1208 to select third power supply rail 1219 for powering amplification circuitry 602 in response to signal Vₛₑₙₛₑ indicating that voltage across load 208 is at least voltage threshold V_{th_2}. In some embodiments, voltage thresholds V_{th_1} and V_{th_2} are provided to control circuitry 1206 by an external source (not shown), as illustrated in FIG. 12. In some other embodiments, voltage thresholds V_{th_1} and V_{th_2} are generated within control circuitry 1206, and in these embodiments, voltage thresholds V_{th_1} and V_{th_2} may be either fixed or programmable.

### Combinations of Features

Features described above may be combined in various ways without departing from the scope hereof. The following examples illustrate some possible combinations:
(A1) A method for providing an analog output signal includes (i) amplifying an analog first internal signal using a first Class-G amplifier to generate an analog first output signal, (ii) providing the analog first output signal to a first load, and (iii) configuring the first Class-G amplifier for an impedance of the first load by selecting one of a plurality of power supply rails to power the first Class-G amplifier at least partially based on a voltage across the first load.
(A2) The method denoted as (A1) may further include determining the voltage across the first load.
(A3) In either one of methods denoted as (A1) or (A2), an impedance of the first load may vary independently of a state of the analog first output signal.
(A4) In any one of the methods denoted as (A1) through (A3), an impedance of the first load may range from zero to 1,000 ohms.
(A5) In any one of the methods denoted as (A1) through (A4), the first load may include an industrial device.
(A6) In any one of the methods denoted as (A1) through (A5), the analog first output signal may be a current signal.
(A7) In any one of the methods denoted as (A1) through (A5), the analog first output signal may be a voltage signal.
(A8) In any one of the methods denoted as (A1) through (A7), selecting one of the plurality of power supply rails to power the first Class-G amplifier at least partially based on the voltage across the first load may include selecting the one of the plurality of power supply rails based on a relationship between (a) the voltage across the first load and (b) a predetermined threshold value.
(A9) In any one of the methods denoted as (A1) through (A8), (i) the plurality of power supply rails may include a first power supply rail and a second power supply rail, and (ii) the method may further include changing a power supply rail powering the first Class-G amplifier from the first power supply rail to the second power supply rail in response to the voltage across the first load crossing a predetermined threshold value.
(A10) In any one of the methods denoted as (A1) through (A9), the plurality of power supply rails may have different respective voltages.
(A11) Any one of the methods denoted as (A1) through (A10) may further include converting a digital signal to the analog first internal signal.
(A12) Any one of the methods denoted as (A1) through (A11) may further include (i) amplifying an analog second internal signal using a second Class-G amplifier to generate an analog second output signal, (ii) providing the analog second output signal to a second load, and (iii) configuring the second Class-G amplifier for an impedance of the second load by selecting one of the plurality of power supply rails to power the second Class-G amplifier at least partially based on a voltage across the second load.
(B1) A programmable controller includes (1) a processing system configured to generate a digital first internal signal at least partially according to programming instructions provided to the processing system, (2) a first digital to analog (D/A) converter configured to convert the digital first internal signal to an analog first internal signal, and (3) a first Class-G amplifier configured to (i) generate an analog first output signal by amplifying the analog first internal signal and (ii) select one of a plurality of power supply rails to power the first Class-G amplifier at least partially based on a voltage across a load powered by the analog first output signal.
(B2) The programmable controller denoted as (B1) may be selected from the group consisting of a programmable logic controller (PLC), a programmable automation controller (PAC), and a controller of a digital control system (DCS).
(B3) Either one of the programmable controllers denoted as (B1) or (B2) may further include a programming interface enabling modification of the programming instructions provided to the processing system.
(B4) In any one of the programmable controllers denoted as (B1) through (B3), the processing system may be further configured to generate the digital first internal signal at least partially according to one or more input signals received by the programmable controller.
(B5) In any one of the programmable controllers denoted as (B1) through (B4), (1) the processing system may be further configured to generate a digital second internal signal at least partially according to programming instructions provided to the processing system, and (2) the programmable controller may further include (i) a second D/A converter configured to convert the digital second internal signal to an analog second internal signal and (ii) a second Class-G amplifier. The second Class-G amplifier may be configured to (1) generate an analog second output signal by amplifying the analog second internal signal and (2) select one of the plurality of power supply rails to power the second Class-G amplifier at least partially based on a voltage across a load powered by the analog second output signal.
(C1) An electrical environment includes a programmable controller and a first load. The programmable controller includes (1) a processing system configured to generate a digital first internal signal at least partially according to programming instructions provided to the processing system, (2) a first digital to analog (D/A) converter configured to convert the digital first internal signal to an analog first internal signal, and (3) a first Class-G amplifier configured to (i) generate an analog first output signal by amplifying the analog first internal signal and (ii) select one of a plurality of power supply rails to power the first Class-G amplifier at least partially based on a voltage across a load powered by the analog first output signal. The first load is powered by the analog first output signal.
(C2) The electrical environment denoted as (C1) may further include an electrical cable electrically coupling the first load to the programmable controller.
(C3) In either one of the electrical environments denoted as (C1) or (C2), an impedance of the first load may range from zero to 1,000 ohms.
(C4) In any one of the electrical environments denoted as (C1) through (C3), the programmable controller may be selected from the group consisting of a programmable logic controller (PLC), a programmable automation controller (PAC), and a controller of a digital control system (DCS)

Changes may be made in the above methods, devices, and systems without departing from the scope hereof. It should thus be noted that the matter contained in the above description and shown in the accompanying drawings should be interpreted as illustrative and not in a limiting sense. The following claims are intended to cover generic and specific features described herein, as well as all statements of the scope of the present method and system, which as a matter of language, might be said to fall therebetween.

What is claimed is:

1. A method for providing an analog output signal, the method comprising:
amplifying an analog first internal signal using a first Class-G amplifier to generate an analog first output signal;
providing the analog first output signal to a first load; and
configuring the first Class-G amplifier for an impedance of the first load by selecting one of a plurality of power supply rails to power the first Class-G amplifier at least partially based on a voltage across the first load.

2. The method of claim 1, further comprising determining the voltage across the first load.

3. The method of claim 1, wherein an impedance of the first load may vary independently of a state of the analog first output signal.

4. The method of claim 1, wherein an impedance of the first load may range from zero to 1,000 ohms.

5. The method of claim 1, wherein the first load comprises an industrial device.

6. The method of claim 1, wherein the analog first output signal is a current signal.

7. The method of claim 1, wherein the analog first output signal is a voltage signal.

8. The method of claim 1, wherein selecting one of the plurality of power supply rails to power the first Class-G amplifier at least partially based on the voltage across the first load comprises selecting the one of the plurality of power supply rails based on a relationship between (a) the voltage across the first load and (b) a predetermined threshold value.

9. The method of claim 1, wherein:
the plurality of power supply rails comprise a first power supply rail and a second power supply rail; and
the method further comprising changing a power supply rail powering the first Class-G amplifier from the first power supply rail to the second power supply rail in response to the voltage across the first load crossing a predetermined threshold value.

10. The method of claim 1, wherein the plurality of power supply rails have different respective voltages.

11. The method of claim 1, further comprising converting a digital signal to the analog first internal signal.

12. The method of claim 1, further comprising:
amplifying an analog second internal signal using a second Class-G amplifier to generate an analog second output signal;
providing the analog second output signal to a second load; and
configuring the second Class-G amplifier for an impedance of the second load by selecting one of the plurality of power supply rails to power the second Class-G amplifier at least partially based on a voltage across the second load.

13. A programmable controller, comprising:
a processing system configured to generate a digital first internal signal at least partially according to programming instructions provided to the processing system;
a first digital to analog (D/A) converter configured to convert the digital first internal signal to an analog first internal signal; and
a first Class-G amplifier configured to:
generate an analog first output signal by amplifying the analog first internal signal, and
select one of a plurality of power supply rails to power the first Class-G amplifier at least partially based on a voltage across a load powered by the analog first output signal.

14. The programmable controller of claim 13, wherein the programmable controller is selected from the group consisting of a programmable logic controller (PLC), a programmable automation controller (PAC), and a controller of a digital control system (DCS).

15. The programmable controller of claim 13, further comprising a programming interface enabling modification of the programming instructions provided to the processing system.

16. The programmable controller of claim 13, wherein the processing system is further configured to generate the digital first internal signal at least partially according to one or more input signals received by the programmable controller.

17. The programmable controller of claim 13, wherein:
the processing system is further configured to generate a digital second internal signal at least partially according to programming instructions provided to the processing system; and
the programmable controller further comprises:
a second D/A converter configured to convert the digital second internal signal to an analog second internal signal, and
a second Class-G amplifier configured to:
generate an analog second output signal by amplifying the analog second internal signal, and
select one of the plurality of power supply rails to power the second Class-G amplifier at least partially based on a voltage across a load powered by the analog second output signal.

18. An electrical environment, comprising:
a programmable controller, including:
a processing system configured to generate a digital first internal signal at least partially according to programming instructions provided to the processing system,
a first digital to analog (D/A) converter configured to convert the digital first internal signal to an analog first internal signal, and
a first Class-G amplifier configured to:
generate an analog first output signal by amplifying the analog first internal signal, and
select one of a plurality of power supply rails to power the first Class-G amplifier at least partially based on a voltage across a load powered by the analog first output signal; and
a first load powered by the analog first output signal.

19. The electrical environment of claim 18, further comprising an electrical cable electrically coupling the first load to the programmable controller.

20. The electrical environment of claim 18, wherein the programmable controller is selected from the group consisting of a programmable logic controller (PLC), a programmable automation controller (PAC), and a controller of a digital control system (DCS).
